(19) United States
(12) Patent Application Publication
(10) Pub. No.: US 2008/0070417 A1
(43) Pub. Date: Mar. 20, 2008

(54) Method of etching semiconductor device and method of fabricating semiconductor device using the same

(75) Inventors: Je-woo Han, Chungcheongnam-do (KR); Myeong-cheol Kim, Suwon-si (KR); Dong-hyun Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/827,450

(22) Filed: Jul. 12, 2007

(30) Foreign Application Priority Data
Sep. 14, 2006 (KR) 10-2006-0089250

(51) Int. Cl. H01L 21/3065

(52) U.S. Cl. 438/714; 257/E21.218

(57) ABSTRACT

A method of fabricating a semiconductor device which prevents a pitting phenomenon from occurring on a gate insulating layer is provided. The method of fabricating of a semiconductor device according to the present invention comprises: depositing a first gate material including at least a gate insulating layer and a first metal layer in a first region on a semiconductor substrate; depositing a second gate material layer including at least a gate insulating layer and a polysilicon layer in a second region on the semiconductor substrate; forming a hard mask pattern on the first gate material layer and on the second gate material layer; and forming a first gate pattern and a second gate pattern by etching the first gate material layer and the second gate material layer, using the hard mask pattern as a mask, wherein the step of forming the first gate pattern and the second gate pattern comprises dry etching the first metal layer and the polysilicon layer simultaneously using a first etching gas composition including both CF₄ and CH₄, such that when the first metal layer is completely etched, a polysilicon layer of at least a predetermined minimum protective thickness remains covering the underlying gate insulating layer. The etch rate of the first metal layer to the etch rate of polysilicon can be relatively increased by the method of this invention, and, as a result, a gate pattern with high density can be effectively formed.

### CROSS-REFERENCE TO RELATED PATENT APPLICATION

This application claims the benefit of Korean Patent Application No. 10-2006-0089250, filed on Sep. 14, 2006, in the Korean Intellectual Property Office, the disclosure of which is incorporated herein in its entirety by reference.

### BACKGROUND OF THE INVENTION

1. Field of the Invention

The present invention relates to a method of etching a semiconductor device and a method of fabricating a semiconductor device using the etching method, and more particularly, to a method of etching a metal layer which increases the etching selectivity of tantalum nitride relative to polysilicon and a method of forming a gate using the same etching method.

2. Description of the Related Art

A charge trap flash (CTF) semiconductor structure using a metal gate in a cell region and a polysilicon gate in a peri region has been developed for nonvolatile flash memory devices.

In a CTF device, tantalum nitride (TaN) is commonly used as a metal gate in a cell region and polysilicon is used as a polysilicon gate in a peri region. That is, the metal gate of the cell region is typically formed by sequentially stacking material layers, such layers typically including a gate insulating layer, a silicon nitride (SiN) layer, an aluminum oxide (AlO) layer, a tantalum nitride (TaN) layer, a tungsten nitride (WN) layer, and a tungsten (W) layer on a semiconductor substrate. The polysilicon gate of the peri region is also typically formed by sequentially stacking material layers, such layers typically including a gate insulating layer, a polysilicon layer, a tungsten nitride (WN) layer, and a tungsten (W) layer on the semiconductor substrate. The metal gate of the cell region and the polysilicon gate of the peri region are formed by etching using an upper hard mask pattern as a mask. A process of etching a gate typically includes a process of etching the tantalum nitride (TaN) layer of the cell region and the polysilicon layer of the peri region simultaneously. While the unmasked portion of the tantalum nitride layer is being etched to an appropriate thickness or to complete removal, the unmasked portion of the polysilicon layer is also being etched, but with the limitation that the polysilicon layer needs to remain of at least a predetermined thickness or greater on the gate insulating layer. When the polysilicon layer does not remain in at least the predetermined thickness or greater on the gate insulating layer throughout this etching step, a pitting phenomenon occurs on the gate insulating layer and such pitting causes problems and leads to performance degradation.

FIG. 1 is a scanning electron microscope (SEM) image, illustrating a pitting phenomenon occurring on a gate insulating layer 22. Referring to FIG. 1, it is noted that pitting can be discerned (inside the portions 12 indicated by the rings) in the gate insulating layer 22. That is, when a polysilicon layer on the gate insulating layer 22 is not maintained at least at a predetermined thickness or greater, parts of the gate insulating layer 22 are damaged by dry etching during a dry etching process, thereby causing pitting. When such pitting occurs on the gate insulating layer, critical failure is likely to be caused in driving a gate. Accordingly, it is necessary to maintain the polysilicon layer on the gate insulating layer at least at the predetermined protective thickness or greater. Two methods can be used to realize this result: one is to originally deposit the polysilicon layer in a relatively thick initial layer; and, the other would be to increase the etching selectivity of tantalum nitride (TaN) relative to polysilicon. However, the approach of depositing a relatively thick initial polysilicon layer results in increasing the total height of a gate. This interferes with a subsequent process and therefore this approach is not desirable. That is, when the total height of the gate is too high, this interferes with a process of filling the gap between gate patterns with an interlayer insulating layer. Furthermore, when the total height of the gate is too high, a step between a cell region and a peri region also becomes high, thereby interfering with a subsequent process of photolithography.

These and other deficiencies in or limitations of the prior art approaches to this problem are addressed in whole or at least in part by the methods of this invention.

### SUMMARY OF THE INVENTION

The present invention provides a method of etching a semiconductor device wherein the etching selectivity of tantalum nitride is increased relative to polysilicon.

The present invention also provides a method of fabricating a semiconductor device using the etching method of this invention which can be used to form a gate pattern.

According to an aspect of the present invention, there is provided a method of etching a semiconductor device comprising: dry etching metal or metal nitride and polysilicon simultaneously, using an etching gas comprising both CF₄ and CH₄.

In the etching gas, the flux (amount) of CF₄ may advantageously be about two to four times greater than the flux of CH₄.

According to another aspect of the present invention, there is provided a method of fabricating a semiconductor device, comprising: depositing a first gate material layer including at least a gate insulating layer and a first metal layer in a first region on a semiconductor substrate; depositing a second gate material layer including at least a gate insulating layer and a polysilicon layer in a second region on the semiconductor substrate; forming a hard mask pattern on the first gate material layer and the second gate material layer; and forming a first gate pattern and a second gate pattern, by etching respectively the first gate material layer and the second gate material layer, using the hard mask pattern as a mask; and wherein the step of forming the first gate pattern and the second gate pattern comprises dry etching the first metal layer and the polysilicon layer simultaneously using a first etching gas including both CF₄ and CH₄, such that, when the first metal layer exposed by the hard mask pattern is completely etched, a polysilicon layer of at least a protective thickness remains on substantially every portion of the surface of the gate insulating layer.

The first metal layer may comprise at least one material selected from the group consisting of Ni, Co, TaN, Ru—Ta, TiN, Ni—Ti, Ti—Al—N, Zr, Hf, Ti, Ta, Mo, MoN, Ta—Pt and Ta—Ti.

The flux of CF₄ may preferably be about two to four times greater than the flux of CH₄ in the first etching gas composition.

The etching of the first metal layer and the polysilicon layer simultaneously, using the first etching gas composition is preferably carried out such that a polysilicon layer in a thickness of at least 150 Å or greater remains on the gate insulating layer when the etching of the first metal layer has been completed.

### BRIEF DESCRIPTION OF THE DRAWINGS

The above and other features and advantages of the present invention will become more apparent by describing in detail exemplary embodiments thereof with reference to the attached drawings in which:

FIG. 1 is a scanning electron microscope (SEM) image, illustrating a pitting phenomenon occurring on a gate insulating layer;

FIG. 2 is a graph illustrating the difference between the etch rate of tantalum nitride (TaN) and the etch rate of polysilicon, using CF₄ as the only active component of an etching gas composition;

FIG. 3 is a graph illustrating the difference between the etch rate of tantalum nitride (TaN) and the etch rate of polysilicon, based on a method of etching a semiconductor device in accordance with an embodiment of the present invention;

FIGS. 4A through 4C are schematic cross-sectional views illustrating a charge trap flash (CTF) gate structure formed by using a method of etching a semiconductor device according to an embodiment of the present invention; and

FIG. 5 is an SEM image, illustrating a section of a polysilicon gate when the thickness of a remaining polysilicon layer after a dry etching process is at least 150 Å.

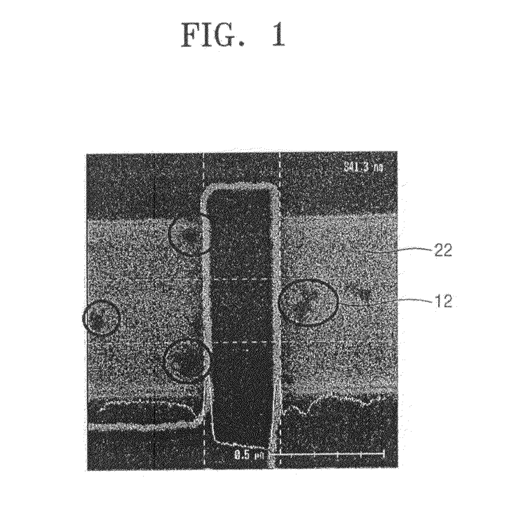

### DETAILED DESCRIPTION OF THE INVENTION

The present invention will now be described more fully hereinafter with reference to the accompanying drawings and tables, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

It will be understood that, when an element, such as layer, region or substrate, is described as being positioned “on” another element, the element may directly contact the other element or there may exist other elements interposed between the two elements.

It will also be understood that relative terms, such as “lower” or “bottom” and “upper” or “top”, are used to describe the relation between elements as illustrated in the drawings. It will be understood that, the relative terms include not only the direction illustrated in the drawings but also other directions and orientations of a device. For example, when a device is turned over in the drawings, an element, which is described as being positioned on the “lower” surface of another element, now has the direction of being positioned on the “upper” surface of the latter element. For example, the term “lower” may include both directions “lower” and “upper”, relatively depending on a specific direction in the drawing. Similarly, when a device is turned over in any one of the drawings, an element, which is described as being positioned “below” or “beneath” another element, now has the direction of “above” relating to the latter element. For example, the term “below” or “beneath” may include both directions “above” and “below” or “beneath”.

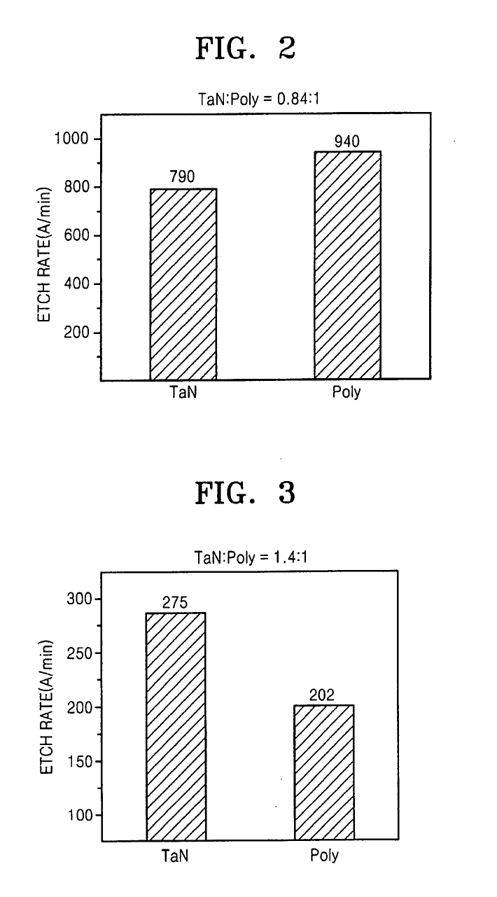

FIG. 2 is a graph illustrating the difference between the etch rate of tantalum nitride (TaN) and the etch rate of polysilicon, using CF₄ as the only active component of an etching gas composition. Referring to FIG. 2, when CF₄ is used as the only active component of an etching gas, the etch rate of tantalum nitride (TaN) is 790 Å/min and the etch rate of polysilicon is 940 Å/min. The ratio of the etch rate of tantalum nitride (TaN) relative to the etch rate of polysilicon is about 0.84:1. As used herein, the statement that CF₄ is used as the etching gas means that the only active component of the etching gas composition is CF₄. Accordingly, helium (He) or argon (Ar), which are inert gases in this application, may be further included as components of this etching gas composition.

As shown in FIG. 2, when CF₄ is used as the only active component of the etching gas composition under etching conditions, it is seen that polysilicon is etched about 1.2 times faster relative to tantalum nitride (TaN). This result has been derived when inductively coupled plasma etching was performed under etching conditions wherein the pressure inside an etching chamber is 10 mTorr, source high-frequency power is 600 W, bias high-frequency power voltage is 100V, and the flux of the etching gas composition is 60 sccm of helium and 60 sccm of CF₄. The unit “sccm” is an abbreviation of standard cubic centimeter per minute. 1 sccm means that the quantity of gas, which flows for one minute at temperature of 0° C. and pressure of 1 atm, is 1 cm³.

A method of etching a semiconductor device according to an embodiment of the present invention will now be described.

FIG. 3 is a graph illustrating the difference between the etch rate of tantalum nitride (TaN) and the etch rate of polysilicon, based on a method of etching a semiconductor device in accordance with an embodiment of the present invention. That is, the graph indicates the difference between the etch rate of tantalum nitride (TaN) and the etch rate of polysilicon, using a combination of CF₄ and CH₄ as the active components of an etching gas composition. As used herein, the statement that CF₄ and CH₄ are used as the etching gas means that the active components of the etching gas composition are CF₄ and CH₄. Accordingly, helium (He) or argon (Ar), which are inert gases in this application, may be further included as components of this etching gas composition.

Referring to FIG. 3, the etch rate of tantalum nitride (TaN) is 275 Å/min and the etch rate of polysilicon is 202 Å/min. Accordingly, the ratio of the etch rate of tantalum nitride (TaN) relative to the etch rate of polysilicon is about 1.4:1. That is, when both CF₄ and CH₄ are used as the active components of an etching gas composition under etching conditions, tantalum nitride (TaN) is etched about 1.4 times faster relative to polysilicon. This result has been derived when inductively coupled plasma etching was performed under etching conditions wherein the pressure inside an etching chamber is 10 mTorr, source high-frequency power is 600 W, bias high-frequency power voltage is 100V, and the flux of the etching gas composition is 60 sccm of helium, 60 sccm of CF₄ and 20 sccm of CH₄, in other words, generally comparable to the etching conditions used in the example illustrated by FIG. 2 apart from the modified etching gas composition. However, the inductively coupled plasma etching in accordance with this invention is not limited to the above-described process conditions. Under a range of conditions, such as wherein the pressure inside the chamber ranges from about 8 to 12 mTorr, source high-frequency power ranges from about 500 to 700 W, and bias high-frequency power voltage ranges from about 20 to 200V, the inductively coupled plasma etching derives substantially the same result that tantalum nitride is etched faster than polysilicon. Comparable results are also realized not only under the experimental condition wherein the flux of the etching gas consists essentially of 60 sccm of CF₄ and 20 sccm of CH₄, but also under the conditions wherein the flux of the etching gas is within the range of about 10 to 30 sccm of CH₄ and the flux ratio of CF₄ to CH₄ ranges from about 2:1 to about 4:1, preferably about 3:1. In other words, when the flux of CF₄ is about two to four times the flux of CH₄, it has been found that the etch rate of tantalum nitride (TaN) is desirably higher than the etch rate of polysilicon thereby facilitating the selective etching of a TaN layer simultaneously with a polysilicon layer without removing too much of the polysilicon layer.

The inductively coupled plasma etching process selectively removes a material layer by both a chemical reaction of a substrate with radicals in a plasma state and a physical method by an accelerating collision of ions, using an inductively coupled plasma (ICP) processing system. The ICP processing system is commonly used by persons skilled in this art, and therefore no further description thereof will be presented here.

Comparing FIG. 2 and FIG. 3, it can be seen that when a combination of CF₄ and CH₄ is used as an etching gas composition, the etch rate of polysilicon relative to TaN is decreased compared to when only CF₄ is used as the etching gas, and the etching selectivity of tantalum nitride (TaN) relative to polysilicon under these conditions selectively increases. It is believed that the mechanism behind this surprising discovery is that, because polymers of the CHx-series, which are generated as by-products of the etching, become attached to the surface of a thin film being etched, the etch rate along that surface is decreased. The decrease in the etch rate of a polysilicon thin film by this mechanism is greater than that of a metal or metal nitride thin film. In the method of etching a semiconductor device in accordance with the embodiment of the present invention, tantalum nitride (TaN) is considered and is herein defined for purposes of this application as a metal thin film. However, the metal thin films of this invention are not limited to tantalum nitride (TaN) but may be selected from the group consisting of thin films composed of metal or metal nitride, for example, a thin film including one or more of Ni, Co, TaN, Ru—Ta, TiN, Ni—Ti, Ti—Al—N, Zr, Hf, Ti, Ta, Mo, MoN, Ta—Pt and Ta—Ti.

A method of fabricating a semiconductor device using the above-described etching method to form a gate pattern in accordance with another embodiment of the present invention will now be described.

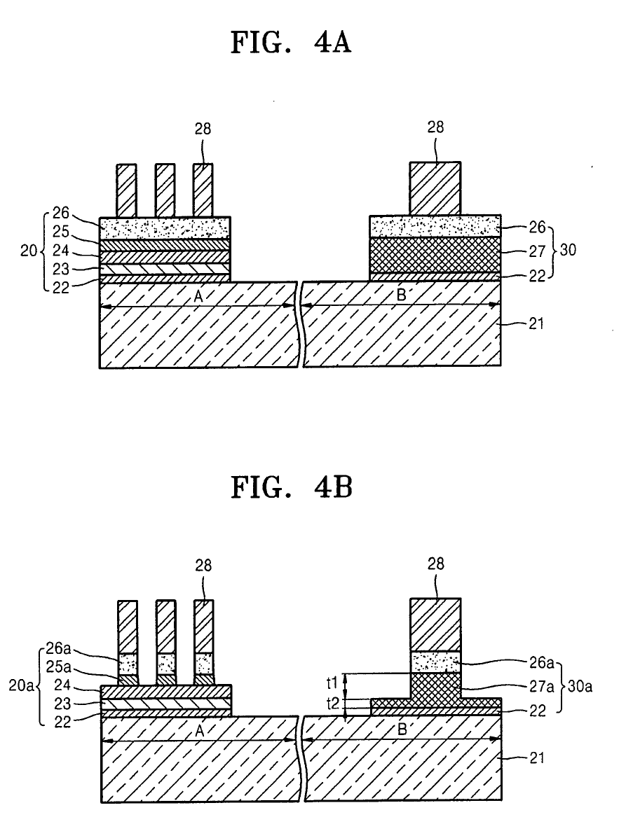

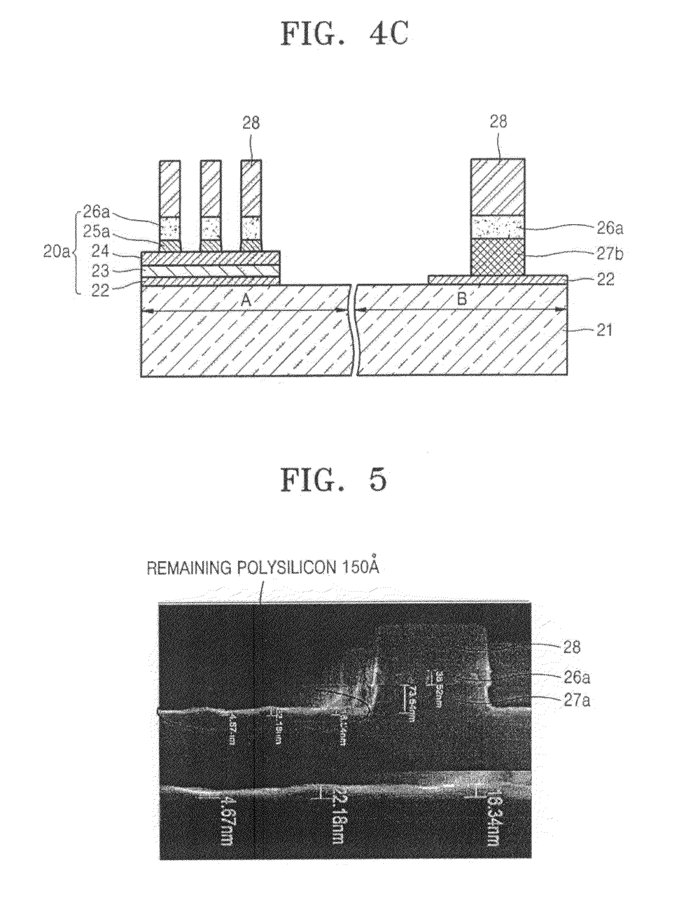

FIGS. 4A through 4C are schematic cross-sectional views illustrating a charge trap flash (CTF) gate structure formed by a method of etching a semiconductor device in accordance with the embodiment of FIG. 3.

Referring to FIG. 4A, a first gate material layer 20 is formed in a cell region A on a semiconductor substrate 21, and a second gate material layer 30 is formed in a peri region B on the semiconductor substrate 21. The first gate material layer 20 may be formed by sequentially stacking material layers including a gate insulating layer 22, a silicon nitride (SiN) layer 23, an aluminum oxide (AlO) layer 24, a first metal layer 25 comprising tantalum nitride (TaN), a tungsten nitride (WN) layer (not shown), and a tungsten (W) layer 26. Tantalum nitride (TaN) in first metal layer 25 may be replaced by another metal thin film, for example, a metal or metal nitride selected from one or more of Ni, Co, TaN, Ru—Ta, TiN, Ni—Ti, Ti—Al—N, Zr, Hf, Ti, Ta, Mo, MoN, Ta—Pt and Ta—Ti.

The second gate material layer 30 may be formed by sequentially stacking material layers including a gate insulating layer 22, a polysilicon layer 27, a tungsten nitride (WN) layer (not shown), and a tungsten (W) layer 26. When the tungsten (W) layer 26 of the cell region A and of the peri region B is about 300 Å in thickness, the tungsten nitride (WN) layer (not shown) may be about 50 Å in thickness. A hard mask pattern 28 is formed on the first gate material layer 20 and also on the second gate material layer 30. The hard mask pattern 28 may be formed of an oxide layer or a nitride layer.

Subsequently, referring now to FIG. 4B, a tungsten pattern 26a is formed by dry etching the tungsten layer 26 and the tungsten nitride layer (not shown) of the cell region A and of the peri region B, using the hard mask pattern 28 as a mask and using SF₆ (sulfur hexafluoride) gas as an etching gas. The statement that SF₆ is used as the etching gas means that the active component of the etching gas composition with an etching effect is SF₆. Accordingly, helium (He) or argon (Ar), which are inert gases in this application, may be further included in the etching gas composition used in this step of the process.

When the tungsten layer 26 of the peri region B is etched simultaneously with etching tungsten layer 26 of the cell region A, the polysilicon layer 27 below the tungsten layer 26 of peri region B may also be partially etched. For example, when the thickness of the tungsten layer 26 is initially 300 Å, the polysilicon layer 27 may be recessed by about 150 Å during the process of etching the tungsten layer 26 to form the tungsten pattern 26a in cell region A.

Subsequently, a tantalum nitride pattern 25a and a polysilicon pattern 27a are formed by dry etching the tantalum nitride layer 25 of the cell region A and the polysilicon layer 27 of the peri region B simultaneously, using a combination of CF₄ and CH₄ as an etching gas composition in accordance with this invention. The statement that a combination of CF₄ and CH₄ is used as the etching gas means that the active components with an etching effect are CF₄ and CH₄. Accordingly, helium (He) or argon (Ar), which are inert gases in this application, may be further included in this etching gas composition. While the tantalum nitride layer 25 is being etched, using the hard mask pattern 28 and the tungsten pattern 26a as a mask, the polysilicon layer 27 of the peri region B is also being etched to the depth t1, and the polysilicon pattern 27a, which remains on gate insulating layer 22 having the thickness t2, is formed. That is, when the first metal layer exposed by the hard mask pattern is completely etched upon dry etching the first metal layer and the polysilicon layer simultaneously using the first etching gas composition consisting essentially of CF₄ and CH₄ in accordance with this invention, at least a portion of the polysilicon layer that remained exposed by the hard mask pattern still remains as a protective layer on the gate insulating layer. Such portion has the thickness t2 as seen in FIG. 4B such that all of the gate insulating layer 22 in peri region B remains covered by polysilicon.

FIG. 5 is an SEM image, illustrating a section of a polysilicon gate when the thickness t2 of the remaining polysilicon in peri region B after the dry etching step is 150 Å. Referring to FIG. 5, the polysilicon gate formed in the peri region includes the hard mask pattern 28, tungsten pattern 26a, and polysilicon pattern 27a. The remaining polysilicon which was not masked by the hard mask pattern 28 during dry etching, has been etched but still maintains a protective thickness t2 (see FIG. 4B) of about 150 Å. As a result, a pitting phenomenon is prevented on the underlying gate insulating layer 22 (of FIG. 4B). It has been found that, when the thickness t2 (see FIG. 4B) of the remaining polysilicon layer is less than 150 Å, however, the pitting phenomenon occurs. To prevent the pitting phenomenon on the underlying gate insulating layer 22, the thickness of the remaining polysilicon layer should be at least the thickness t2, i.e., 150 Å or more, on the underlying gate insulating layer.

Subsequently, now referring to FIG. 4C, the remaining polysilicon (the portion not masked by hard mask pattern 28) formed in the peri region B is removed by dry etching, using the hard mask pattern 28 as a mask.

For this step, the etching gas may advantageously include HBr and O₂. The statement that a combination of HBr and O₂ is used as the etching gas means that the active components having an etching effect are HBr and O₂. Accordingly, helium (He) or argon (Ar), which are inert gases in this application, may be further included as part of this etching gas composition. The etching gas composition of HBr and O₂, which has high selectivity to an oxide layer, prevents the pitting phenomenon from affecting the gate insulating layer 22 while still effectively removing the remaining polysilicon which is not masked by the hard mask pattern 28.

A method of forming a gate pattern using the above-described etching method in accordance with an embodiment of the present invention is more effective in improving the performance characteristics of a semiconductor device as the critical dimensions of the semiconductor device gradually become smaller and many circuits are to be formed in a small area. That is, as the gate critical dimensions in the cell region become smaller, many more gate patterns need to be formed in the smaller area, which is commonly referred to as a high density gate. Accordingly, a loading effect may occur during the etching process. That is, as the critical dimensions become smaller, etching particles may have difficulty in entering between patterns and, as a result, the etch rate decreases. Consequently, when forming the metal gate pattern of the cell region, the etch rate of the tantalum nitride (TaN) layer is decreased by such a loading effect. As a result, it takes a longer time to etch the metal layer having a certain thickness, that is, the tantalum nitride layer. This in turn means that the etch amount of the polysilicon layer in the peri region that is etched also increases. However, when the etched amount of the polysilicon layer of the peri region becomes greater than necessary, the pitting phenomenon is caused on the underlying gate insulating layer. Accordingly, fabricating a CTF device having high density requires an etching process with high etching selectivity of tantalum nitride relative to polysilicon. Such an etching process is realized by using the combination etching gas of this invention consisting essentially of CH₄ and CF₄, which is described above in greater detail with reference to the embodiment of FIG. 3 of the present invention.

The method of etching a semiconductor device in accordance with the present invention relatively increases the etch rate of tantalum nitride to the etch rate of polysilicon by using a combination etching gas including both CF₄ and CH₄. Furthermore, the above-described etching method of forming a gate according to the present invention can be used effectively to form a high density gate pattern.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of etching as a step in fabricating a semiconductor device, said method comprising the step of: dry etching an unmasked metal or metal nitride surface and an unmasked polysilicon surface simultaneously using an etching gas composition comprising both CF₄ and CH₄.

2. The method of claim 1, wherein the metal or metal nitride includes at least one material selected from the group consisting of W, Ni, Co, TaN, Ru—Ta, TiN, Ni—Ti, Ti—Al—N, Zr, Hf, Ti, Ta, Mo, MoN, WN, Ta—Pt and Ta—Ti.

3. The method of claim 1, wherein in the etching gas composition the flux of CF₄ ranges from about two to four times the flux of CH₄.

4. The method of claim 1, wherein in the etching gas composition the flux of CH₄ is in the range of about 10 to 30 sccm, and the flux ratio of CF₄ to CH₄ is about 3:1.

5. The method of claim 4, wherein the etching gas composition further includes helium (He) or argon (Ar).

6. The method of claim 1, wherein the step of dry etching comprises inductively coupled plasma etching.

7. The method of claim 6, wherein the inductively coupled plasma etching is performed inside a chamber at a pressure of about 8 to 12 mTorr, at a source high-frequency power of about 500 to 700 W, and at a bias high-frequency power voltage of about 20 to 200V.

8. A method of fabricating a semiconductor device comprising the steps of:
depositing a first gate material layer including at least a gate insulating layer and a first metal layer in a first region on a semiconductor substrate;
depositing a second gate material layer including at least a gate insulating layer and a polysilicon layer in a second region on the semiconductor substrate;
forming a hard mask pattern on the first gate material layer and on the second gate material layer; and
forming a first gate pattern and a second gate pattern by etching the first gate material layer and the second gate material layer respectively using the hard mask pattern as a mask;
wherein a step in the method of forming of the first gate pattern and the second gate pattern comprises dry etching the first metal layer and the polysilicon layer simultaneously using a first etching gas composition including both CF₄ and CH₄ such that, when at least a portion of the first metal layer not masked by the hard mask pattern has been completely etched, at least a portion of the polysilicon layer not masked by the hard mask pattern remains on the gate insulating layer.

9. The method of claim 8, wherein the first metal layer includes at least one material selected from the group consisting of Ni, Co, TaN, Ru—Ta, TiN, Ni—Ti, Ti—Al—N, Zr, Hf, Ti, Ta, Mo, MoN, Ta—Pt and Ta—Ti.

10. The method of claim 8, wherein the hard mask pattern is formed of an oxide layer or a nitride layer.

11. The method of claim 8, wherein the gate insulating layer includes at least one layer of an insulating material selected from the group consisting of silicon oxide (SiO₂), silicon oxy nitride (SiON), silicon nitride (SiN), metal oxide and metal silicate.

12. The method of claim 8, wherein the step of depositing the first gate material layer comprises sequentially stacking material layers including: a gate insulating layer; a silicon nitride (SiN) layer; an aluminum oxide (AlO) layer; a first metal layer wherein the first metal comprises tantalum nitride; a tungsten nitride (WN) layer; and a tungsten (W) layer.

13. The method of claim 8, wherein the step of depositing the second gate material layer comprises sequentially stacking material layers including: a gate insulating layer; a polysilicon layer; a tungsten nitride (WN) layer; and a tungsten (W) layer.

14. The method of claim 12, wherein a step in the method of forming of the first gate pattern and the second gate pattern comprises dry etching the tungsten nitride (WN) layer and the tungsten (W) layer using a second etching gas including SF₆.

15. The method of claim 13, wherein a step in the method of forming of the first gate pattern and the second gate pattern comprises dry etching the tungsten nitride (WN) layer and the tungsten (W) layer using a second etching gas including SF₆.

16. The method of claim 8, wherein the step of dry etching comprises inductively coupled plasma etching.

17. The method of claim 16, wherein the inductively coupled plasma etching is performed inside a chamber at a pressure of about 8 to 12 mTorr, at a source high-frequency power of about 500 to 700 W, and at a bias high-frequency power voltage of about 20 to 200V.

18. The method of claim 8, wherein, when the portion of the first metal layer not masked by the hard mask pattern has been completely etched, the portion of the polysilicon layer not masked by the hard mask pattern remains in a thickness of 150 Å or greater on the gate insulating layer.

19. The method of claim 8, further comprising the steps of dry etching the portion of the polysilicon layer not masked by the hard mask pattern and remaining on the gate insulating layer after etching with the first etching gas composition using a third etching gas composition and thereby removing the unmasked portion of the polysilicon layer.

20. The method of claim 19, wherein the third etching gas composition includes HBr and O₂.

21. The method of claim 8, wherein the first region is a cell region and the second region is a peri region.

22. The method of claim 8, wherein in the first etching gas composition the flux of CF₄ ranges from about two to four times the flux of CH₄.

23. The method of claim 22, wherein in the first etching gas composition the flux of CH₄ is in the range of about 10 to 30 sccm, and the flux ratio of CF₄ to CH₄ is about 3:1.

24. The method of claim 23, wherein the first etching gas composition further includes helium (He) or argon (Ar).
